(19) United States
(12) Patent Application Publication
(10) Pub. No.: US 2026/0053015 A1
(43) Pub. Date: Feb. 19, 2026

(54) SEMICONDUCTOR PACKAGE

(71) Applicant: Samsung Electronics Co., Ltd., Suwon-si, Gyeonggi-do (KR)

(72) Inventor: Jitaek Oh, Suwon-si, Gyeonggi-do (KR)

(21) Appl. No.: 19/085,266

(22) Filed: Mar. 20, 2025

(30) Foreign Application Priority Data
Aug. 13, 2024 (KR) 10-2024-0108493

(51) Int. Cl. H01L 23/00; H01L 23/538; H01L 25/065; H10B 80/00

(52) U.S. Cl. CPC H01L 24/49; H01L 23/5386; H01L 24/06; H01L 24/48; H01L 25/0657; H01L 2224/06131; H01L 2224/48145; H01L 2224/48229; H01L 2224/4846; H01L 2224/48463; H01L 2224/4847; H01L 2224/48476; H01L 2224/49052; H01L 2224/49109; H01L 2224/49112; H01L 2224/49174; H01L 2225/06506; H01L 2225/0651; H01L 2225/06562; H01L 2924/386; H10B 80/00

(57) ABSTRACT

A semiconductor package includes a package substrate including first and second power P-pads and first and second signal P-pads, a lower layer chip including first and second power L-pads and first and second signal L-pads, an upper layer chip offset from the lower layer chip and including first and second power U-pads and first and second signal U-pads. The first power and signal P-pads are alternatingly stacked, the first power and signal L-pads are alternatingly stacked, and the first power and signal U-pads are alternatingly stacked. The second power and signal P-pads are alternatingly stacked, the second power and signal L-pads are alternatingly stacked, and the second power and signal U-pads are alternatingly stacked. Bonding wires connect the first and second power U-pads, the first and second power L-pads, the second power U-pads and P-pads, and the second signal U-pads and P-pads.

### CROSS-REFERENCE TO RELATED APPLICATION

This application is based on and claims priority under 35 U.S.C. § 119 to Korean Patent Application No. 10-2024-0108493, filed on Aug. 13, 2024, in the Korean Intellectual Property Office, the disclosure of which is incorporated by reference herein in its entirety.

### TECHNICAL FIELD

The present disclosure relates to a semiconductor package, and more particularly, to a semiconductor package including bonding wires.

### BACKGROUND

The semiconductor package may be manufactured by mounting a semiconductor chip on a printed circuit board and connecting chip pads included in the semiconductor chip to pads included in the printed circuit board by using bonding wires. Recently, a structure in which multiple chips are stacked in one package is used to provide highly integrated and high-capacity memory.

In the structure in which multiple chips are stacked, multiple bonding wires connecting pads included in the multiple chips to pads included in the printed circuit board have a complex connection structure. Accordingly, there has been a desire for a method to improve the characteristics of signals input to or output from each chip by optimizing the connection structure of multiple bonding wires and to prevent electrical shorts between the bonding wires.

### SUMMARY

The present disclosure provides a semiconductor package capable of operating in half-bandwidth mode by connecting multiple chips stacked in steps to a package substrate through an optimal bonding wire structure.

The present disclosure is not limited to the description mentioned above, and other embodiments not mentioned are clearly understood by those skilled in the art from the description below.

According to an aspect of the present disclosure, there is provided a semiconductor package including a package substrate including first power P-pads and second power P-pads configured to transmit power/ground signals and first signal P-pads and second signal P-pads configured to transmit data signals. The semiconductor package includes a lower layer chip that is on the package substrate and includes first power L-pads and second power L-pads configured to transmit the power/ground signals and first signal L-pads and second signal L-pads configured to transmit the data signals. The semiconductor package includes an upper layer chip that is on and offset from the lower layer chip in a first direction that is parallel to an upper surface of the package substrate, the upper layer chip including first power U-pads and second power U-pads configured to transmit the power/ground signals and first signal U-pads and second signal U-pads configured to transmit the data signals. In a first region of the package substrate, the first power P-pads and the first signal P-pads are alternatingly stacked in a second direction that is parallel to the upper surface of the package substrate, the first power L-pads and the first signal L-pads are alternatingly stacked in the second direction, and the first power U-pads and the first signal U-pads are alternatingly stacked in the second direction. In a second region of the package substrate that is spaced apart from the first region in the second direction, the second power P-pads and the second signal P-pads are alternatingly stacked in the second direction, the second power L-pads and the second signal L-pads are alternatingly stacked in the second direction, and the second power U-pads and the second signal U-pads are alternatingly stacked in the second direction. The semiconductor package includes a plurality of bonding wires that electrically connect the first power U-pads and the second power U-pads and the first power L-pads and the second power L-pads to each other, respectively, the second power U-pads and the second power P-pads to each other, and the second signal U-pads and the second signal P-pads to each other.

According to another aspect of the present disclosure, there is provided a semiconductor package including a package substrate including first power P-pads and second power P-pads configured to transmit power/ground signals, and first signal P-pads and second signal P-pads configured to transmit data signals. The semiconductor package includes first to fourth chips that are stacked on top of each other, offset from each other in a first direction that is perpendicular to an upper surface of the package substrate, and on the package substrate, where each of the first to fourth chips includes first power pads and second power pads configured to transmit the power/ground signals and first signal pads and second signal pads configured to transmit the data signals. In a first region of the package substrate, the first power P-pads and the first signal P-pads are alternatingly stacked in a second direction that is parallel to the upper surface of the package substrate, and the first power pads and the first signal pads of each of the first to fourth chips are alternatingly stacked in the second direction. In a second region of the package substrate that is spaced apart from the first region in the second direction, the second power P-pads and the second signal P-pads are alternatingly stacked in the second direction, and the second power pads and the second signal pads of each of the first to fourth chips are alternatingly stacked in the second direction. The semiconductor package includes a plurality of bonding wires that electrically connect the first power pads and the second power pads of the second to fourth chips to each other, the first power pads and the second power pads of the first to third chips to each other, the second power pads of the second and fourth chips and the second power P-pads to each other, and the second signal pads of the second and fourth chips and the second signal P-pads to each other.

According to another aspect of the present disclosure, there is provided a semiconductor package including a package substrate including a first channel and a second channel, the first channel including first power P-pads, second power P-pads, first signal P-pads and second signal P-pads, the second channel including first power P-pads, second power P-pads, first signal P-pads and second signal P-pads. The semiconductor package includes first to fourth chips that are stacked on top of each other, offset from each other in a first direction that is perpendicular to an upper surface of the package substrate, and on the package substrate, where each of the first to fourth chips includes first and second power pads configured to transmit power/ground signals and first and second signal pads configured to transmit data signals. In a first region of the package substrate, the first power P-pads and the first signal P-pads of the first channel are alternatingly stacked in a second direction that is parallel to the upper surface of the package substrate, the first power P-pads and the first signal P-pads of the second channel are alternatingly stacked in the second direction, and the first power pads and the first signal pads of each of the first to fourth chips are alternatingly stacked in the second direction. In a second region of the package substrate that is spaced apart from the first region in the second direction, the second power P-pads and the second signal P-pads of the first channel are alternatingly stacked in the second direction, the second power P-pads and the second signal P-pads of the second channel are alternatingly stacked in the second direction, and the second power pads and second signal pads of each of the first to fourth chips are alternatingly stacked in the second direction. The semiconductor package includes a plurality of bonding wires that electrically connect the first power pads and the second power pads of the second to fourth chips and the first power pads and the second power pads of the first to third chips, respectively, to each other, the second power pads of the second chip and the second power P-pads of the first channel to each other, the second power pads of the fourth chip and the second power P-pads of the second channel to each other, the second signal pads of the second chip and the second signal P-pads of the first channel to each other, and the second signal pads of the fourth chip and the second signal P-pads of the second channel to each other.

### BRIEF DESCRIPTION OF THE DRAWINGS

Embodiments will be more clearly understood from the following detailed description taken in conjunction with the accompanying drawings in which:

FIG. 1 is a block diagram illustrating the operation of a semiconductor package according to an embodiment;

FIG. 2A is a perspective view of a semiconductor package according to an embodiment;

FIG. 2B a plan view of a semiconductor package according to an embodiment;

FIG. 2C is a cross-sectional view of a semiconductor package, taken along line I-I′ in FIG. 2B, according to an embodiment;

FIG. 2D is a cross-sectional view of a semiconductor package, taken along line II-II′ in FIG. 2B, according to an embodiment;

FIG. 2E is an enlarged cross-sectional view of portion A in FIG. 2D of a semiconductor package, according to an embodiment;

FIG. 3 is a block diagram illustrating the operation of a semiconductor package according to an embodiment;

FIG. 4A is a perspective view of a semiconductor package according to an embodiment;

FIG. 4B a plan view of a semiconductor package according to an embodiment;

FIG. 4C is a cross-sectional view of a semiconductor package, taken along line I-I′ in FIG. 4B, according to an embodiment;

FIG. 4D is a cross-sectional view of a semiconductor package, taken along line II-II′ in FIG. 4B, according to an embodiment;

FIG. 4E is an enlarged cross-sectional view of portion A in FIG. 4D of a semiconductor package, according to an embodiment;

FIG. 5 is a block diagram illustrating the operation of a semiconductor package according to an embodiment;

FIG. 6A is a perspective view of a semiconductor package according to an embodiment;

FIG. 6B a plan view of a semiconductor package according to an embodiment;

FIG. 6C is a cross-sectional view of a semiconductor package, taken along line I-I′ in FIG. 6B, according to an embodiment; and

FIG. 6D is a cross-sectional view of a semiconductor package, taken along line II-II′ in FIG. 6B, according to an embodiment.

### DETAILED DESCRIPTION

Hereinafter, the embodiments are described in detail with reference to the attached drawings. The same reference numerals are used for the same components in the drawings and duplicate descriptions thereof are omitted.

To clarify the present disclosure, the same elements or equivalents are referred to by the same reference numerals throughout the specification. Further, since sizes and thicknesses of constituent members shown in the accompanying drawings are arbitrarily given for better understanding and case of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction. The terms “first,” “second,” etc. may be used herein to merely distinguish one component, element, etc., from another.

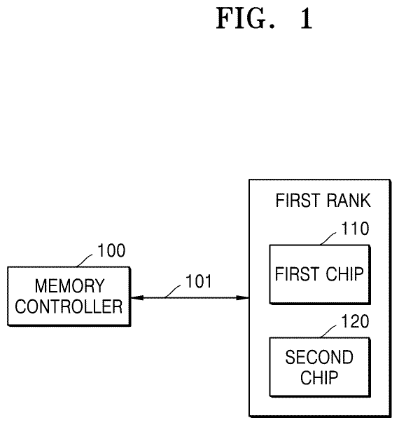

FIG. 1 is a block diagram illustrating the operation of a semiconductor package 10 according to an embodiment.

The semiconductor package 10 may include a first chip 110 and a second chip 120, which are included in a first rank. The first chip 110 and the second chip 120 may include memory chips that store data. For example, the first chip 110 and the second chip 120 may include a dynamic random-access memory (DRAM) chip, a static random-access memory (SRAM) chip, a NAND flash memory chip, a phase-change random-access memory (PRAM) chip, a resistive random-access memory (RRAM) chip, a ferroelectric random-access memory (FeRAM) chip, and/or a magnetoresistive random-access memory (MRAM).

A memory controller 100 shown in FIG. 1 may perform control operations for the semiconductor package 10 and/or memory access (read or write) for the semiconductor package 10. The memory controller 100 may communicate with the semiconductor package 10 through a channel 101.

According to an embodiment, the channel 101 may include data lines transmitting a data signal (e.g., DQ[0:15]), chip select signal lines transmitting a chip select signal, and command/address signal lines transmitting a command/address.

The memory controller 100 may provide a data signal to the first rank or may receive a data signal output from the first rank through data lines included in the channel 101. As an example, the memory controller 100 may provide a 16-bit data signal to the first rank.

The semiconductor package 10 may operate in half-bandwidth mode. The half-bandwidth mode refers to processing, by each of two semiconductor chips included in one rank, a half of the data signal input to one rank or a half of the data signal output from one rank. For example, as shown in FIG. 1, when the first chip 110 and the second chip 120 are included in the first rank, each of the first chip 110 and the second chip 120 may perform an operation of writing a half of the data signal input to the first rank.

According to an embodiment, the semiconductor package 10 may operate in byte mode. The byte mode, which is included in the half-bandwidth mode, refers to processing, by each of two chips included in one rank, a data signal of 1 byte. Specifically, when a 16-bit data signal (DQ[0:15]) is input to the first rank through the data lines included in the channel 101, the first chip 110 may write only a lower byte (DQ[0:7]) and the second chip 120 may write only an upper byte (DQ[8:15]).

Although it is illustrated above that the first chip 110 and the second chip 120 included in the first rank can process data in units of 1 byte, this is only an example. The first chip 110 and the second chip 120 may process data in units of 10 bits or 12 bits and operate in half-bandwidth mode in various units.

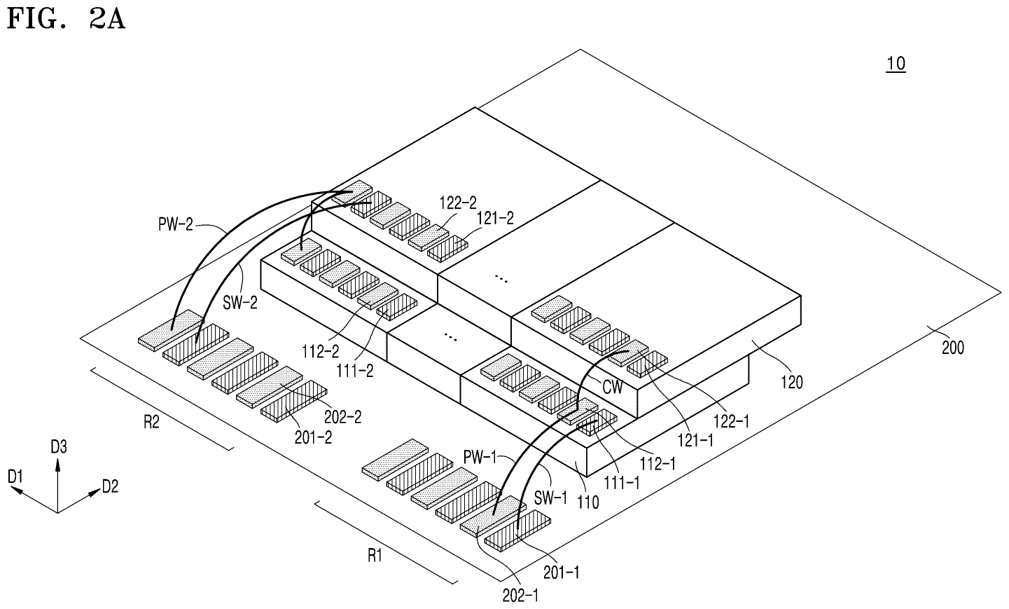

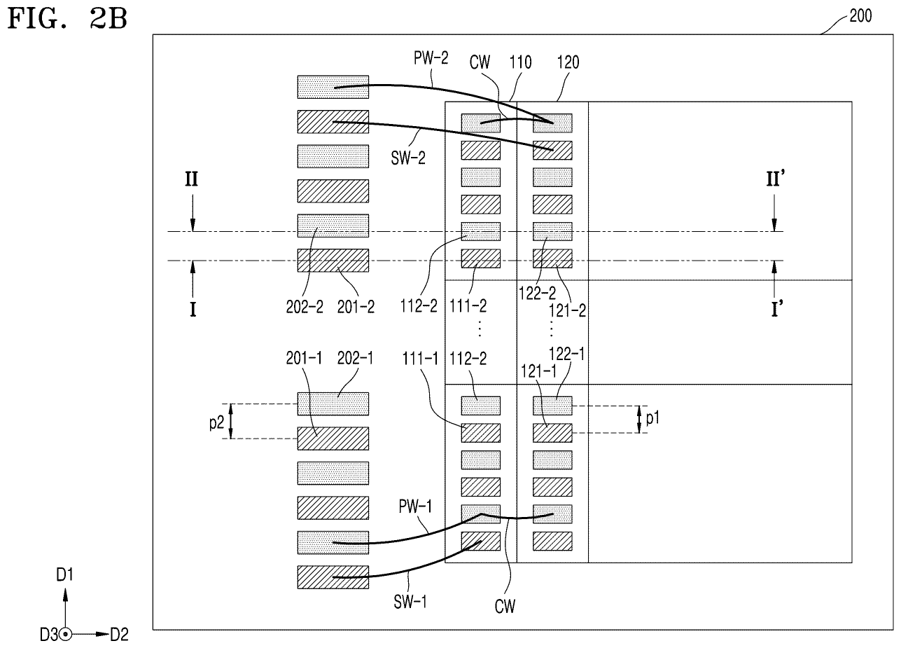

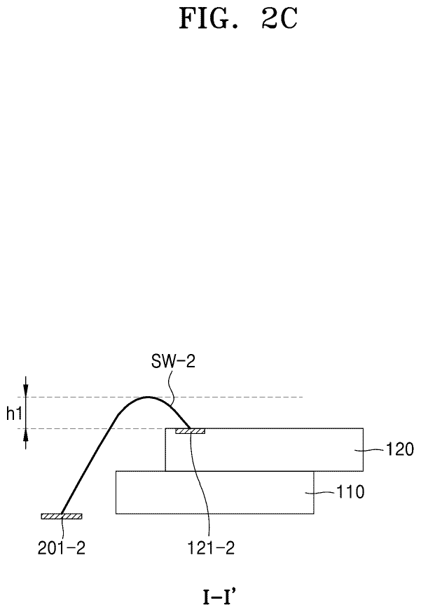

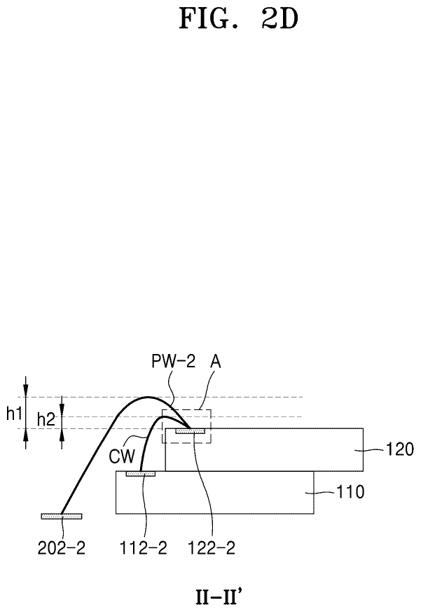

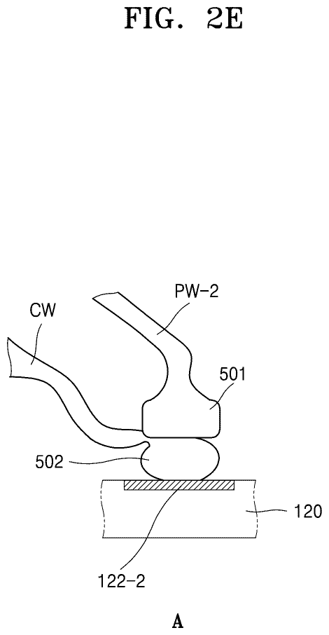

As stated above, in order for the first chip 110 and second chip 120, which are included in the same rank, to operate in half-bandwidth mode, the first chip 110 and the second chip 120 may be connected to signal P-pads and power P-pads included in a package substrate through bonding wires. Thus, the connection structure of the bonding wires included in the semiconductor package 10 may be described in detail with reference to FIGS. 2A to 2E below.

FIG. 2A is a perspective view of a semiconductor package 10 according to an embodiment. FIG. 2B is a plan view of the semiconductor package 10, according to an embodiment, viewed from a position moved or offset in a third direction D3.

Referring to FIGS. 2A and 2B, the semiconductor package 10 may include a package substrate 200, a first chip 110 disposed on the package substrate 200, and a second chip 120 disposed in steps on the first chip 110.

The package substrate 200 may include various types of substrates, such as a printed circuit board (PCB), a flexible substrate, and a tape substrate. As an example, the package substrate 200 may include a PCB on which internal wires are formed. The package substrate 200 may include first signal P-pads 201-1, second signal P-pads 201-2, first power P-pads 202-1, and second power P-pads 202-2 disposed on the package substrate 200. Additionally, the package substrate 200 may include connection pads disposed on a lower surface of the package substrate 200. The first signal P-pads 201-1, the second signal P-pads 201-2, the first power P-pads 202-1, and the second power P-pads 202-2 may be connected to the connection pads through the internal wires, wherein connection terminals, such as solder balls or solder bumps, may be attached to the connection pads.

The first chip 110 may include memory chips that store data. The first chip 110 may be bonded to the package substrate 200 by an adhesive layer. The first chip 110 may include first signal L-pads 111-1, second signal L-pads 111-2, first power L-pads 112-1, and second power L-pads 112-2, which are placed on the edge of the first chip 110.

The second chip 120 may also include a memory chip with the same characteristics as the first chip 110. The second chip 120 may be bonded to the first chip 110 by an adhesive layer and may be stacked in a stepped structure. The second chip 120 may be stacked in steps at a position moved or offset in a second direction D2 with respect to a position where the first chip 110 is bonded to the package substrate 200. The second chip 120 may include first signal U-pads 121-1, second signal U-pads 121-2, first power U-pads 122-1, and second power U-pads 122-2, which are placed on the edge of the second chip 120.

Herein, signal pads, such as the first signal L-pads 111-1, the second signal U-pads 121-2, and the first signal P-pads 201-1, may include pads for inputting and outputting data signals. Additionally, power pads, such as the first power L-pads 112-1, the second power U-pads 122-2, and the first power P-pads 202-1, may include pads for inputting and outputting power or ground signals.

The electrical connection is made between first power L-pads 112-1 and the first power U-pads 122-1 and between the second power L-pads 112-2 and the second power U-pads 122-2. The electrical separation or isolation is made between the first signal L-pads 111-1 and the first signal U-pads 121-1 and between the second signal L-pads 111-2 and the second signal U-pads 121-2.

An alternating arrangement may be made in a first direction D1 in a first region R1 between the first power P-pads 202-1 and the first signal P-pads 201-1, between the first power L-pads 112-1 and the first signal L-pads 111-1, and between the first power U-pads 122-1 and the first signal U-pads 121-1 (e.g., the respective elements are alternatingly stacked in the first direction).

In addition, an alternating arrangement may be made in the first direction D1 in a second region R2 between the second power P-pads 202-2 and the second signal P-pads 201-2, between the second power L-pads 112-2 and the second signal L-pads 111-2, and between the second power U-pads 122-2 and the second signal U-pads 121-2 (e.g., the respective elements are alternatingly stacked in the first direction).

The first region R1 may be separate or spaced apart from the second region R2. Specifically, the first region R1 may include a region of the semiconductor package 10 where the first signal P-pads 201-1 and the first power P-pads 202-1 are arranged and may extend in the second direction D2 and/or the third direction D3. The second region R2 may include a region of the semiconductor package 10 where the second signal P-pads 201-2 and the second power P-pads 202-2 are arranged and may extend in the second direction D2 and/or the third direction D3.

In the first region R1 and the second region R2, the connection through chip-to-chip wires CW may be made between the first power L-pads 112-1 and the first power U-pads 122-1 and between the second power L-pads 112-2 and the second power U-pads 122-2.

In the first region R1, the first signal L-pads 111-1 may be connected to the first signal P-pads 201-1 through first signal wires SW-1 and the first power L-pads 112-1 may be connected to the first power P-pads 202-1 through first power wires PW-1. In first region R1, the first signal U-pads 121-1 are not connected to other pads through bonding wires.

In the second region R2, the second signal U-pads 121-2 may be connected to the second signal P-pads 201-2 through second signal wires SW-2 and the second power U-pads 122-2 may be connected to the second power P-pads 202-2 through second power wires PW-2. In the second region R2, the second signal L-pads 111-2 are not connected to other pads through bonding wires.

Herein, the terms “chip-to-chip wires,” “power wires,” and “signal wires” are included in or refer to the bonding wires that connect pads included in multiple chips and/or pads included in the package substrate 200 to each other.

Specifically, the term “chip-to-chip wires” used herein may refer to bonding wires connecting power pads included in a first chip other than the lowest layer chip in the third direction D3 to power pads included in a second chip placed one layer below the first chip in the third direction D3, in a structure where multiple chips are stacked in steps on a package substrate. As an example, as shown in FIGS. 2A and 2B, the bonding wires connecting the first power U-pads 122-1 of the second chip 120 to the first power L-pads 112-1 of the first chip 110 include the chip-to-chip wires CW.

In addition, the term “power wires” used herein may refer to bonding wires directly connecting power pads included in chips to power pads included in the package substrate 200, in a structure where multiple chips are stacked in steps on a package substrate. For example, as shown in FIGS. 2A and 2B, the bonding wires directly connecting the first power L-pads 112-1 of the first chip 110 to the first power P-pads 202-1 of the package substrate 200 include the first power wires PW-1 and the bonding wires directly connecting the second power U-pads 122-2 of the second chip 120 to the second power P-pads 202-2 of the package substrate 200 include the second power wires PW-2.

In addition, the term “signal wires” used herein may refer to bonding wires directly connecting signal pads included in chips to signal pads included in the package substrate 200, in a structure where multiple chips are stacked in steps on a package substrate. For example, as shown in FIGS. 2A and 2B, the bonding wires directly connecting the first signal L-pads 111-1 of the first chip 110 to the first signal P-pads 201-1 of the package substrate 200 include the first signal wires SW-1 and the bonding wires directly connecting the second signal U-pads 121-2 of the second chip 120 to the second signal P-pads 201-2 of the package substrate 200 include the second signal wires SW-2.

As shown above, as the first signal L-pads 111-1 included in the first chip 110 are connected to the first signal P-pads 201-1 of the package substrate 200 in the first region R1 and the second signal U-pads 121-2 included in the second chip 120 are connected to the second signal P-pads 201-2 of the package substrate 200 in the second region R2, the semiconductor package 10 may operate in half-bandwidth mode.

Specifically, the semiconductor package 10 may write a first half or portion of the data signal input to the first chip 110 of the first rank based on the data lines formed through the first signal wires SW-1 in the first region R1 and may write the other half or portion of the data signal to the second chip 120 based on the data lines formed through the second signal wires SW-2 in the second region R2. Although it is illustrated above that the semiconductor package 10 may write the data signal in the half-bandwidth mode, this is only an example. The semiconductor package 10 may read the data signal through half-bandwidth mode.

According to an embodiment, in order for the semiconductor package 10 to operate in half-bandwidth mode, the number of first signal L-pads 111-1, the number of first signal U-pads 121-1, the number of second signal L-pads 111-2, and the number of second signal U-pads 121-2 may correspond to half of the number of data bits input to or output from the first rank.

As an example, when the unit of data signal input to or output from the first rank is 16 bits, the number of first signal L-pads 111-1, the number of first signal U-pads 121-1, the number of second signal L-pads 111-2, and the number of second signal U-pads 121-2 may be 8. Accordingly, the number of first power L-pads 112-1 arranged alternately with the first signal L-pads 111-1 may be 8. According to the same principle, the number of first power U-pads 122-1, the number of second power L-pads 112-2, and the number of second power U-pads 122-2 may be 8.

As another example, when the unit of data signal input to or output from the first rank is 24 bits, the number of first signal L-pads 111-1, the number of first signal U-pads 121-1, the number of second signal L-pads 111-2, and the number of second signal U-pads 121-2 may be 12. Accordingly, the number of first power L-pads 112-1 arranged alternately with the first signal L-pads 111-1 may be 12. According to the same principle, the number of first power U-pads 122-1, the number of second power L-pads 112-2, and the number of second power U-pads 122-2 may be 12.

Although three bonding wires in the first region R1 and three bonding wires in the second region R2 are shown in FIGS. 2A and 2B, this is only an example for convenience of explanation. The other pads in the first region R1 and the second region R2 may also be connected to other pads through bonding wires having the same connection structure as the bonding wires shown in FIGS. 2A and 2B.

In other words, the other pads in the first region R1 may also be connected to other pads through bonding wires having the same connection structure as the three bonding wires in the first region R1 shown in FIGS. 2A and 2B. In addition, the other pads in the second region R2 may also be connected to other pads through bonding wires having the same connection structure as the three bonding wires in the second region R2 shown in FIGS. 2A and 2B.

As shown in FIGS. 2A and 2B, the second signal U-pads 121-2 may be connected to the second signal P-pads 201-2 through the second signal wires SW-2. In addition, the second power U-pads 122-2 may be connected to the second power P-pads 202-2 through the second power wires PW-2 and may be connected to the second power L-pads 112-2 through the chip-to-chip wires CW.

The connection structure of the second signal U-pads 121-2 and the second power U-pads 122-2 in the second region R2 through bonding wires may be described in detail along with the structures shown in FIGS. 2C to 2E.

FIG. 2C is a cross-sectional view of a semiconductor package, taken along line I-I′ in FIG. 2B, according to an embodiment. FIG. 2D is a cross-sectional view of a semiconductor package, taken along line II-II′ in FIG. 2B, according to an embodiment. FIG. 2E is an enlarged cross-sectional view of portion A in FIG. 2D of a semiconductor package, according to an embodiment.

Referring to FIG. 2C, the second signal wires SW-2 may include bonding wires connecting the second signal U-pads 121-2 to the second signal P-pads 201-2. The second signal wires SW-2 may include bonding wires having a direct wiring structure. The direct wiring structure may refer to a structure directly connecting chip pads included in chips to pads included in the package substrate 200.

The second signal wire SW-2 may include a bonding ball (e.g., a conductive bump) forming a bond with one of the second signal U-pads 121-2 and a bonding stitch forming a bond with one of the second signal P-pads 201-2. Additionally, the loop height of the second signal wires SW-2 may is denoted as “h1”. The loop height may refer to a distance in the third direction D3 between a starting point of the bonding wires of one of the first chip 110 or the second chip 120 (e.g., a location at which the bonding wire is connected to one of the first chip 110 or the second chip 120) and a highest point of the bonding wires.

Referring to FIG. 2D, the second power wires PW-2 may include bonding wires having a direct wiring structure that directly connect the second power U-pads 122-2 to the second power P-pads 202-2. The second power wires PW-2 may have the same loop height as the second signal wires SW-2. The second power wire PW-2 may include a bonding ball forming a bond with one of the second power U-pads 122-2 and a bonding stitch forming a bond with one of the second power P-pads 202-2.

The chip-to-chip wires CW may include bonding wires directly connecting the second power U-pads 122-2 to the second power L-pads 112-2. In addition, the chip-to-chip wires CW may have a lower loop height h2 than the second power wires PW-2. The chip-to-chip wire CW may include a bonding ball forming a bond with one of the second power U-pads 122-2 and a bonding stitch forming a bond with one of the second power L-pads 112-2.

According to an embodiment, as shown in portion A of FIG. 2D, the second power wires PW-2 and chip-to-chip wires CW may contact each other on an upper surface of one of the second power U-pads 122-2. The structure in which the second power wires PW-2 and the chip-to-chip wires CW contact each other may be described with reference to FIG. 2E.

Referring to FIG. 2E, the second power wires PW-2 and the chip-to-chip wires CW may contact each other on the upper surface of one of the second power U-pads 122-2. Specifically, a bonding ball 502 of the chip-to-chip wire CW (e.g., a conductive bump) may be placed on the upper surface of one of the second power U-pads 122-2 and a bonding ball 501 of the second power wire PW-2 may be placed on top of the bonding ball 502 of the chip-to-chip wire CW.

The wire extending from the bonding ball 502 of the chip-to-chip wire CW may be bent in a horizontal direction (e.g., one of the first or second directions D1, D2) rather than extending vertically upward (e.g., the third direction D3). On the other hand, the wire extending from the bonding ball 501 of the second power wire PW-2 may extend vertically upward without being bent in the horizontal direction. As shown in FIG. 2E, the second power wires PW-2 and the chip-to-chip wires CW include different structures. Accordingly, the bonding ball 501 of the second power wire PW-2 may be stably positioned on top of the bonding ball 502 of the chip-to-chip wire CW and the second power wire PW-2 may stably contact the chip-to-chip wire CW on the upper surface of one of the second power U-pads 122-2.

Referring to FIGS. 2D and 2E, since the bonding ball 501 of the second power wire PW-2 is placed on top of the bonding ball 502 of the chip-to-chip wire CW, the chip-to-chip wires CW may be formed first, and then the second power wires PW-2 may be formed. In addition, the manufacturing process of the second signal wires SW-2 may be performed alternately with the manufacturing process of the chip-to-chip wires CW and the second power wires PW-2. Specifically, in the second region R2, one second signal wire may be formed, then one chip-to-chip wire may be formed, and one second power wire may be formed. Afterwards, one second signal wire may be formed again.

Referring again to FIGS. 2A and 2B, the chip-to-chip wires CW may contact the first power wires PW-1 on an upper surface of one of the first power L-pads 112-1. Unlike the structure shown in FIG. 2E, on the upper surface of one of the first power L-pads 112-1, the bonding stitch of the chip-to-chip wire CW may be placed on the upper surface of one of the first power L-pads 112-1 and the bonding ball of the first power wire PW-1 may be placed on top of the bonding stitch of the chip-to-chip wire CW. As the bonding ball is placed on top of the bonding stitch, which has a relatively flat structure compared to the bonding ball, the chip-to-chip wire CW may stably contact the first power wire PW-1 on the upper surface of one of the first power L-pads 112-1.

Referring again to FIG. 2B, a pitch p2 between the first signal P-pad 201-1 and the first power P-pad 202-1 may be greater than a pitch p1 between the first signal U-pad 121-1 and the first power U-pad 122-1. Accordingly, the horizontal angle (e.g., the angle relative to the first and second directions D1, D2) of the first signal wires SW-1 and the horizontal angle of the first power wires PW-1 may not be the same. According to the same principle, the horizontal angle of the second signal wires SW-2 and the horizontal angle of the second power wires PW-2 may not be the same.

The electrical shorts may occur when bonding wires having different horizontal angles extend from different vertical levels in the same region. For example, electrical shorts may occur between bonding wires when the power wires in the second region R2 have a cascade wiring structure and the signal wires in the second region R2 have a direct wiring structure directly connecting the chip pads of the second chip 120 to the pads of the package substrate 200.

The cascade wiring structure may refer to a structure in which the pads included in the upper layer chip are connected to the pads included in the lower layer chip through bonding wires and only the pads included in the lowest layer chip are directly connected to the pads on the package substrate through bonding wires. In other words, according to the cascade wiring structure, only the pads included in the lowest layer chip among multiple chips stacked in steps may be directly connected to the pads on the package substrate 200 and the pads of each of the other chips than the lowest layer chip may be connected to the pads included in the lower layer chip through chip-to-chip wires.

When the signal wires have a direct wiring structure and the power wires have a cascade wiring structure in the second region R2, the signal wires extending from the second chip 120 and the power wires extending from the first chip 110 may contact each other, thereby causing electrical shorts, because the signal wires extending from the second chip 120 and the power wires extending from the first chip 110 do not include bonding wires extending from the same vertical level.

However, according to the present disclosure, the first signal wires SW-1 and the first power wires PW-1 both include bonding wires extending from the vertical level of the first chip 110. In other words, the first signal wires SW-1 and the first power wires PW-1 include bonding wires extending from the same vertical level. Accordingly, although the horizontal angles of the first signal wires SW-1 and the first power wires PW-1 are not the same, the two wires do not contact each other. Accordingly, the electrical shorts between the two wires do not occur or are inhibited. According to the same principle as described above, the second signal wires SW-2 and the second power wires PW-2 do not contact each other despite the difference in horizontal angles. Thus, the electrical shorts between the two wires do not occur or are inhibited.

Referring again to FIGS. 2A to 2C, the second signal U-pads 121-2 of the second chip 120 may be directly connected to the second signal P-pads 201-2 through the second signal wires SW-2. In other words, the second signal U-pads 121-2 of the second chip 120 may be connected to the second signal P-pads 201-2 through the direct wiring structure rather than the cascade wiring structure. As the second signal U-pads 121-2 are directly connected to the second signal P-pads 201-2 through the direct wiring structure, the characteristics of data signal input to or output from the second signal U-pads 121-2 may be improved, compared to when connected through the cascade wiring structure.

By including the above-described connection structure of bonding wires, the semiconductor package 10 according to the present disclosure may improve the characteristics of data signal as well as prevent or inhibit electrical shorts between bonding wires.

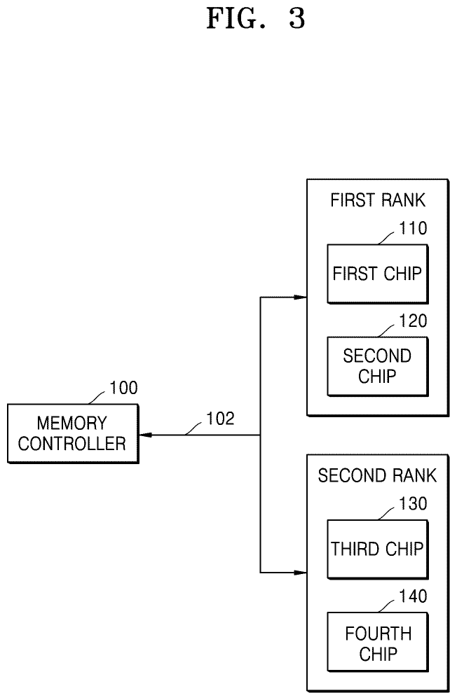

FIG. 3 is a block diagram illustrating the operation of a semiconductor package 11 according to an embodiment.

The semiconductor package 11 may include a first chip 110 and a second chip 120, which are included in a first rank, and a third chip 130 and a fourth chip 140, which are included in a second rank. The third chip 130 and the fourth chip 140 may include memory chips that store data. As an example, the third chip 130 and the fourth chip 140 may include a DRAM chip, a SRAM chip, a NAND flash memory chip, a PRAM chip, a RRAM chip, a FeRAM chip, or a MRAM chip. Since the descriptions of the first chip 110 and the second chip 120 overlap with the previously described embodiments, the descriptions that are substantially the same as those given above may be omitted.

A memory controller 100 shown in FIG. 3 may communicate with the semiconductor package 11 through a channel 102.

According to an embodiment, the channel 102 may include data lines for the first rank and data lines for the second rank. When the first chip 110 and the second chip 120 included in the first rank are activated and the third chip 130 and the fourth chip 140 included in the second rank are not activated, based on the chip select signal, only the first chip 110 and the second chip 120 may write data or read data. On the contrary, when only the third chip 130 and the fourth chip 140 included in the second rank are activated and the first chip 110 and the second chip 120 included in the first rank are not activated, based on the chip select signal, only the third chip 130 and the fourth chip 140 may write data or read data.

As described above, the semiconductor package 11 configured as a dual rank may also operate in the half-bandwidth mode. For example, as shown in FIG. 3, when the third chip 130 and the fourth chip 140 are included in the second rank, each of the third chip 130 and the fourth chip 140 may write a half of the data signal input to the second rank.

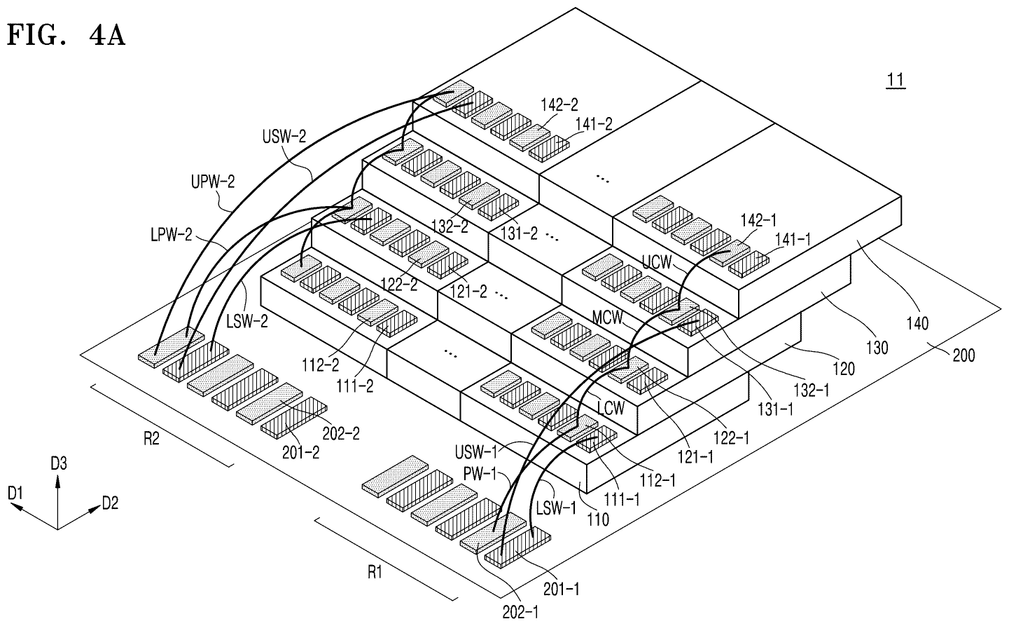

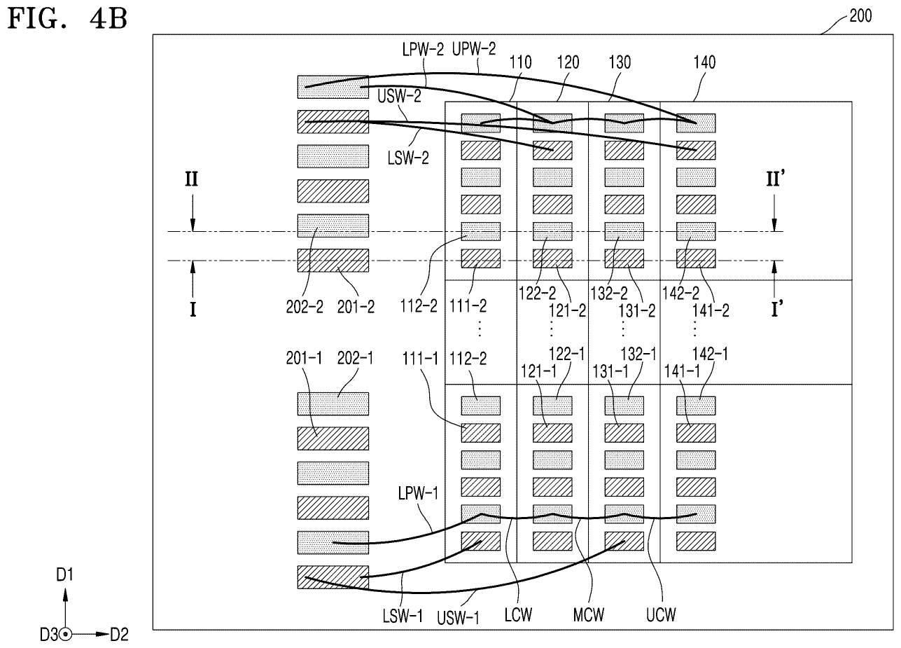

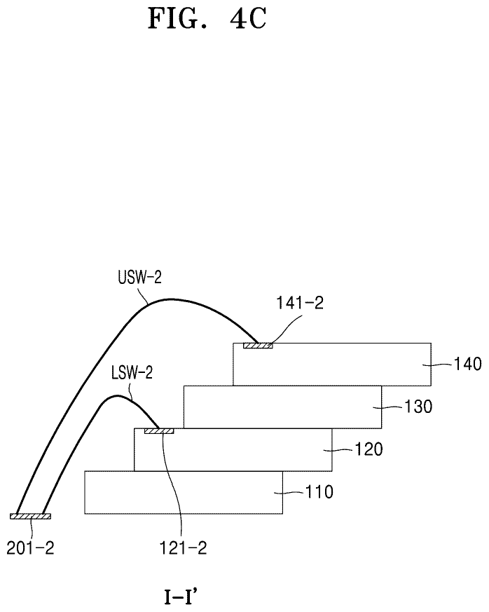

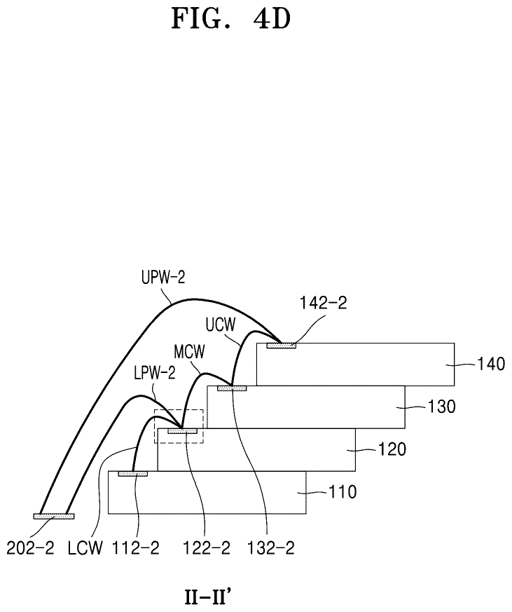

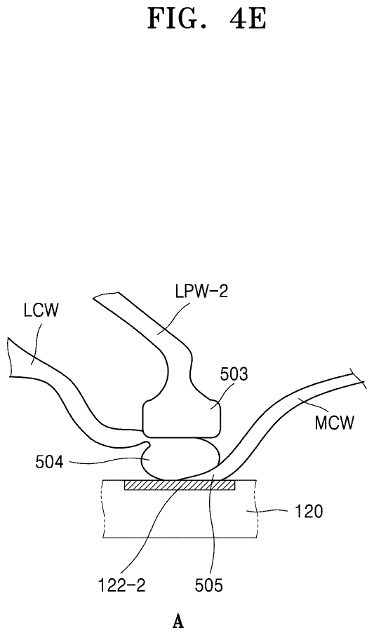

The connection structure of the bonding wires of the semiconductor package 11 may be described in detail with reference to FIGS. 4A to 4E below.

First signal pads 111-1, first power pads 112-1, second signal pads 111-2, and second power pads 112-2 of a first chip 110 shown in FIGS. 4A to 4E may refer to the first signal L-pads 111-1, the first power L-pads 112-1, the second signal L-pads 111-2, and the second power L-pads 112-2, respectively, described with reference to FIGS. 2A to 2E.

In addition, first signal pads 121-1, first signal pads 121-1, first power pads 122-1, second signal pads 121-2, and second power pads 122-2 of a second chip 120 shown in FIGS. 4A to 4E may refer to the first signal U-pads 121-1, the first power U-pads 122-1, the second signal U-pads 121-2, and the second power U-pads 122-2, respectively, described with reference to FIGS. 2A to 2E.

FIG. 4A is a perspective view of a semiconductor package 11 according to an embodiment. FIG. 4B is a plan view of the semiconductor package 11, according to an embodiment, viewed from a position moved in the third direction D3.

Referring to FIGS. 4A and 4B, the semiconductor package 11 may include a package substrate 200, a first chip 110, a second chip 120, a third chip 130, and a fourth chip 140, which are stacked in steps on the package substrate 200 in the second direction D2.

The first to fourth chips 110, 120, 130, and 140 may each include first and second power pads and first and second signal pads. The first signal pads 111-1, 121-1, 131-1, and 141-1 and the first power pads 112-1, 122-1, 132-1, and 142-1 included in the first to fourth chips 110, 120, 130, and 140, respectively, may be arranged alternately in the first direction D1 in the first region R1. In addition, the second signal pads 111-2, 121-2, 131-2, and 141-2 and the second power pads 112-2, 122-2, 132-2, and 142-2 included in the first to fourth chips 110, 120, 130, and 140, respectively, may be arranged alternately in the second direction D2 in the second region R2.

The first power pads 112-1, 122-1, 132-1, and 142-1 included in the first to fourth chips 110, 120, 130, and 140, respectively, may be electrically connected to each other and the second power pads 112-2, 122-2, 132-2, and 142-2 included in the first to fourth chips 110, 120, 130, and 140, respectively, may be electrically connected to each other. The connection between the first power pads 112-1, 122-1, 132-1, and 142-1 and the connection between the second power pads 112-2, 122-2, 132-2, and 142-2 may be formed through chip-to-chip wires CW.

The chip-to-chip wires CW may include lower chip-to-chip wires LCW, middle chip-to-chip wires MCW, and upper chip-to-chip wires UCW. The lower chip-to-chip wires LCW may include bonding wires connecting the power pads of the first chip 110 to the power pads of the second chip 120, the middle chip-to-chip wires MCW may include bonding wires connecting the power pads of the second chip 120 to the power pads of the third chip 130, and the upper chip-to-chip wires UCW may include bonding wires connecting the power pads of the third chip 130 to the power pads of the fourth chip 140.

The first power pads 112-1 of the first chip 110 may be connected to the first power P-pads 202-1 through the first power wires PW-1. In other words, in the first region R1, the first power pads 112-1, 122-1, 132-1, and 142-1 of the first to fourth chips 110, 120, 130, and 140 may be connected to the first power P-pads 202-1 through the cascade wiring structure.

The second power pads 122-2 and 142-2 of the even-numbered chips (the second chip 120 and the fourth chip 140) may be connected to the second power P-pads 202-2 through the second lower power wires LPW-2 and the second upper power wires UPW-2. In other words, the second power pads 122-2 and 142-2 of the even-numbered chips in the second region R2 may be connected to the second power P-pads 202-2 through the direct wiring structure.

The second lower power wires LPW-2 may include bonding wires connecting the second power pads 122-2 of the second chip 120 to the second power P-pads 202-2 and the second upper power wires UPW-2 may include bonding wires connecting the second power pads 142-2 of the fourth chip 140 to the second power P-pads 202-2.

The first signal pads 111-1, 121-1, 131-1, and 141-1 included in the first to fourth chips 110, 120, 130, and 140, respectively, may not be electrically connected to each other and the second signal pads 111-2, 121-2, 131-2, and 141-2 included in the first to fourth chips 110, 120, 130, and 140, respectively, may not be electrically connected to each other. The signal pads 111-1, 121-1, 131-1, and 141-1 and the second signal pads 111-2, 121-2, 131-2, and 141-2 may be connected to the first signal P-pads 201-1 or the second signal P-pads 201-2 through the direct wiring structure.

In the first region R1, the first signal pads 111-1 and 131-1 of the odd-numbered chips (the first chip 110 and the third chip 130) may be connected to the first signal P-pads 201-1 through the first lower signal wires LSW-1 and the first upper signal wires USW-1, respectively.

The first lower signal wires LSW-1 may include bonding wires connecting the first signal pads 111-1 of the first chip 110 to the first signal P-pads 201-1 and the first upper signal wires USW-1 may include bonding wires connecting the first signal pads 131-1 of the third chip 130 to the first signal P-pads 201-1.

In the second region R2, the second signal pads 121-2 and 141-2 of the even-numbered chips (the second chip 120 and the fourth chip 140) may be connected to the second signal P-pads 201-2 through the second lower signal wires LSW-2 and the second upper signal wires USW-2, respectively.

The second lower signal wires LSW-2 may include bonding wires connecting the second signal pads 121-2 of the second chip 120 to the second signal P-pads 201-2 and the second upper signal wires USW-2 may include bonding wires connecting the second signal pads 141-2 of the fourth chip 140 to the second signal P-pads 201-2.

Through the connection structure of the bonding wires described above, the first chip 110 and the second chip 120 included in the first rank, and the third chip 130 and fourth chip 140 included in the second rank may each operate in the half-bandwidth mode.

According to an embodiment, in order for the semiconductor package 11 to operate in half-bandwidth mode, the number of first signal pads 111-1, 121-1, 131-1, and 141-1 and the number of second signal pads 111-2, 121-2, 131-2, and 141-2, included in the first to fourth chips 110, 120, 130, and 140, respectively, may correspond to half of the number of data bits input to or output from the first rank or the second rank.

As an example, when the unit of data signal input to or output from the first rank or the second rank is 16 bits, the number of first signal pads 111-1 of the first chip 110, the number of second signal pads 111-2 of the first chip 110, the number of first signal pads 121-1 of the second chip 120, and the number of second signal pads 121-2 of the second chip 120 may be 8.

As another example, when the unit of data signal input to or output from the first rank or the second rank is 24 bits, the number of first signal pads 111-1 of the first chip 110, the number of second signal pads 111-2 of the first chip 110, and the number of first signal pads 121-1 of the second chip 120 may be 12.

Although six bonding wires in the first region R1 and seven bonding wires in the second region R2 are shown in FIGS. 4A and 4B, this is only an example for convenience of explanation. The other pads in the first region R1 and the second region R2 may also be connected to other pads through bonding wires having the same connection structure as the bonding wires shown in FIGS. 4A and 4B.

Specifically, the other pads in the first region R1 may also be connected to each other through bonding wires having the same connection structure as the connection structure of the six bonding wires shown in the first region R1 in FIGS. 4A and 4B. In addition, the other pads in the second region R2 may also be connected to each other through bonding wires having the same connection structure as the connection structure of the seven bonding wires shown in the second region R2 in FIGS. 4A and 4B.

The connection structure of the second signal pads 111-2, 121-2, 131-2, and 141-2 and the second power pads 112-2, 122-2, 132-2, and 142-2 of the first to fourth chips 110, 120, 130, and 140 in the second region R2 through bonding wires may be described along with the structures shown in FIGS. 4C to 4E.

FIG. 4C is a cross-sectional view of a semiconductor package, taken along line I-I′ in FIG. 4B, according to an embodiment. FIG. 4D is a cross-sectional view of a semiconductor package, taken along line II-II′ in FIG. 4B, according to an embodiment. FIG. 4E is an enlarged cross-sectional view of portion A in FIG. 4D of a semiconductor package, according to an embodiment.

Referring to FIG. 4C, the second lower signal wires LSW-2 may include bonding wires connecting the second signal pads 121-2 of the second chip 120 to the second signal P-pads 201-2. The second upper signal wires USW-2 may include bonding wires connecting the second signal pads 141-2 of the fourth chip 140 to the second signal P-pads 201-2.

A bonding stitch of the second lower signal wire LSW-2 may be placed in a front region of an upper surface of one of the second signal P-pads 201-2. A bonding stitch of the second upper signal wire USW-2 may be placed in a rear region of the upper surface of one of the second signal P-pads 201-2. When the upper surface of each of the second signal P-pads 201-2 is divided into two regions with the same area by a straight line parallel to the first direction D1, the front region may refer to a region adjacent to the first chip 110 among the two regions. In addition, when the upper surface of each of the second signal P-pads 201-2 is divided into two regions with the same area as described above, the rear region may refer to the other region than the front region among the two regions.

For example, when the upper surface of each of the second signal P-pads 201-2 has a vertical length of 200 μm (e.g., a length in the second direction), the bonding stitch of the second lower signal wire LSW-2 may be placed in the front region with a vertical length of 100 μm adjacent to the first chip 110 and the bonding stitch of the second upper signal wire USW-2 may be placed in the other rear region with a vertical length of 100 μm.

Referring to FIG. 4D, the second lower power wires LPW-2 may include bonding wires connecting the second power pads 122-2 of the second chip 120 to the second power P-pads 202-2 and the second upper power wires UPW-2 may include bonding wires connecting the second power pads 142-2 of the fourth chip 140 to the second power P-pads 202-2.

The bonding stitch of the second lower power wire LPW-2 may be placed in the front region of the upper surface of the second power P-pad 202-2 and the bonding stitch of the second upper power wire UPW-2 may be placed in the rear region of the upper surface of the second power P-pad 202-2.

Although it is described that only the bonding stitches of the two bonding wires in the second region may form a bond with one pad in the front region and the rear region of the pad, respectively, bonding stitches of two bonding wires in the first region may form a bond with one pad according to the same principle.

According to an embodiment, as shown in portion A of FIG. 4D, the middle chip-to-chip wires MCW, the lower chip-to-chip wires LCW, and the second lower power wires LPW-2 may contact each other on the upper surface of one of the second power pads 122-2 of the second chip 120. The structure in which the middle chip-to-chip wires MCW, the lower chip-to-chip wires LCW, and the second lower power wires LPW-2 are in contact with each other may be described with reference to FIG. 4E.

Referring to FIG. 4E, the middle chip-to-chip wires MCW, the lower chip-to-chip wires LCW, and the second lower power wires LPW-2 may be in contact with each other on the upper surface of one of the second power pads 122-2 of the second chip 120. Specifically, a bonding stitch 505 of the middle chip-to-chip wire MCW may be placed on the upper surface of one of the second power pads 122-2 of the second chip 120 and a bonding ball 504 of the lower chip-to-chip wire LCW may be placed on top of the bonding stitch 505 of the middle chip-to-chip wire MCW. In addition, the bonding ball 503 of the second lower power wire LPW-2 may be placed on top of the bonding ball 504 of the lower chip-to-chip wire LCW.

The wire extending from the bonding ball 504 of the lower chip-to-chip wire LCW may be bent in the horizontal direction. Through the structure as shown in FIG. 4E, the middle chip-to-chip wires MCW, the lower chip-to-chip wires LCW, and the second lower power wires LPW-2 may form stable contact on the upper surface of one of the second power pads 122-2 of the second chip 120.

Referring again to FIG. 4D, the upper chip-to-chip wires UCW may contact the second upper power wires UPW-2 on the upper surface of one of the second power pads 142-2 of the fourth chip 140. Since the structure in which the upper chip-to-chip wires UCW are in contact with the second upper power wires UPW-2 is the same as the structure shown in FIG. 2E, the descriptions that are substantially the same as those given above.

Referring to FIGS. 4D and 4E, on the upper surface of one of the second power pads 122-2 of second chip 120, the bonding ball 504 of the lower chip-to-chip wire LCW may be placed on top of the bonding stitch 505 of the middle chip-to-chip wire MCW and the bonding ball 503 of the second lower power wires LPW-2 may be placed on top of the bonding ball 504 of the lower chip-to-chip wire LCW. In addition, the bonding ball of the middle chip-to-chip wire MCW may be placed on top of the bonding stitch of the upper chip-to-chip wire UCW on the upper surface of one of the second power pads 132-2 of the third chip 130 and the bonding ball of the second upper power wire UPW-2 may be placed on top of the bonding ball of the upper chip-to-chip wire UCW on the upper surface of one of the second power pads 142-2 of the fourth chip 140.

In order for the semiconductor package 11 to include the bonding wire connection structure as described above, the upper chip-to-chip wires UCW may be formed first, then the middle chip-to-chip wires MCW may be formed, and then the lower chip-to-chip wires LCW may be formed. Thereafter, the second lower power wires LPW-2 may be formed and then the second upper power wires UPW-2 may be formed. That is, the first manufacturing process of the bonding wires shown in FIG. 4D may be performed in the order of “forming the upper chip-to-chip wires UCW, forming the middle chip-to-chip wires MCW, forming the lower chip-to-chip wires LCW, forming the second lower power wires LPW-2, and forming the second upper power wires UPW-2”.

In addition, the second manufacturing process of the bonding wires shown in FIG. 4C may be performed in the order of “forming the second lower signal wires LSW-2, and forming the second upper signal wires USW-2”. Additionally, the second manufacturing process may be performed alternately with the first manufacturing process.

As an example, when the number of each of the second signal pads 111-2, 121-2, 131-2, and 141-2 included in the first to fourth chips 110, 120, 130, and 140, respectively, is 8, the first manufacturing process and the second manufacturing process may be performed alternately 8 times.

Although FIG. 4E illustrates that the bonding ball 504 of the lower chip-to-chip wire LCW and the bonding ball 503 of the second lower power wire LPW-2 may be stacked above the bonding stitch 505, this is only an example. After the bonding ball 504 of the lower chip-to-chip wire LCW is placed on the upper surface of one of the second power pads 122-2 of the second chip 120 and the bonding stitch 505 of the middle chip-to-chip wire MCW is placed above the bonding ball 504 of the lower chip-to-chip wire LCW, the bonding ball 503 of the second lower power wire LPW-2 may be placed above the bonding stitch 505. In this case, the first manufacturing process may be performed in the order of “forming the lower chip-to-chip wires LCW, forming the middle chip-to-chip wires MCW, forming the upper chip-to-chip wires UCW, forming the second lower power wires LPW-2, and forming the second upper power wires UPW-2”.

Referring again to FIGS. 4A and 4B, the second upper power wires UPW-2 and the second upper signal wires USW-2 include bonding wires extending from the same vertical level (the vertical level of the fourth chip 140 in the third direction D3). Therefore, although there is a difference in the horizontal angle between the second upper power wires UPW-2 and the second upper signal wires USW-2, the two wires do not contact each other. According to the same principle, the second lower power wires LPW-2 and second lower signal wires LSW-2 do not contact each other and the first power wires PW-1 and first lower signal wires LSW-1 also do not contact each other.

However, the second upper power wires UPW-2 and the second lower signal wires LSW-2 include bonding wires extending from the vertical level of the fourth chip 140 and the vertical level of the second chip 120, respectively. Additionally, there is a difference in the horizontal angle between the second upper power wires UPW-2 and the second lower signal wires LSW-2. In other words, the second upper power wires UPW-2 and the second lower signal wires LSW-2 include bonding wires extending from different vertical levels and have different horizontal angles.

However, according to the present disclosure, the second upper power wire UPW-2 may be bonded to the rear region of the upper surface of the second power P-pad 202-2 through the bonding stitch and the second lower signal wire LSW-2 may bonded to the front region of the upper surface of the second signal P-pad 201-2 through the bonding stitch. Accordingly, as shown in FIGS. 4C and 4D, the curve of the second upper power wires UPW-2 may have a greater radius of curvature than the curve of the second lower signal wires LSW-2. As the second upper power wires UPW-2 and the second lower signal wires LSW-2 each have a different radius of curvature, the two bonding wires may not contact each other.

Based on the same principle as described above, the second upper signal wires USW-2 may not contact the second lower power wires LPW-2 and the first power wires PW-1 may not contact the first upper signal wires USW-1.

As described above, since the bonding wires included in the semiconductor package 11 according to the present disclosure do not contact each other, the electrical shorts between the bonding wires may not occur or be inhibited.

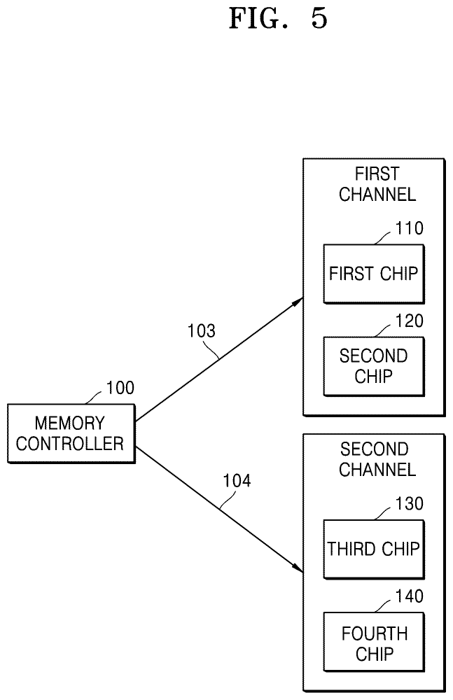

FIG. 5 is a block diagram illustrating the operation of a semiconductor package 12, according to an embodiment.

The semiconductor package 12 may include a first chip 110 and a second chip 120, which are included in a first channel, and a third chip 130 and a fourth chip 140, which are included in a second channel. Since the first to fourth chips 110, 120, 130, and 140 are the same as those described above, descriptions that are substantially the same as those given above may be omitted.

A memory controller 100 may independently provide or receive the data signal through a first channel line 103 and a second channel line 104.

According to an embodiment, the memory controller 100 may provide a first data signal (e.g., DQ[0:15]) to the first chip 110 and the second chip 120 through the first channel line 103 and may provide a second data signal (e.g., DQ[16:31]) to the third chip 130 and the fourth chip 140 through the second channel line 104.

As the first chip 110 and the second chip 120 operate in half-bandwidth mode, each of the first chip 110 and the second chip 120 may process a data signal corresponding to half of the data width of the first data signal. Similarly, as the third chip 130 and the fourth chip 140 operate in half-bandwidth mode, each of the third chip 130 and the fourth chip 140 may process a data signal corresponding to half of the data width of the second data signal.

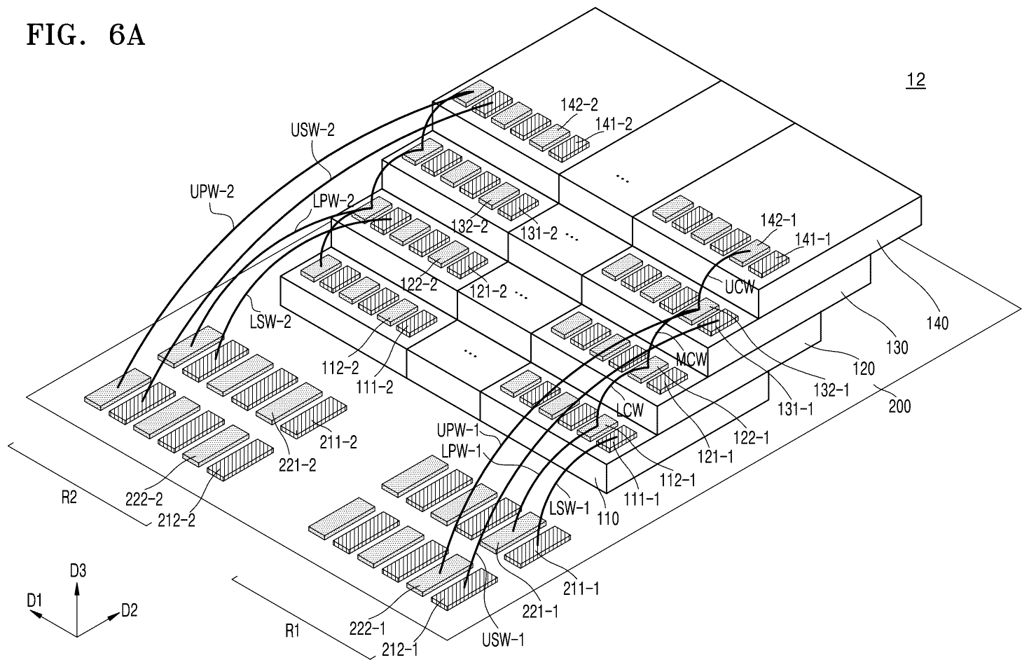

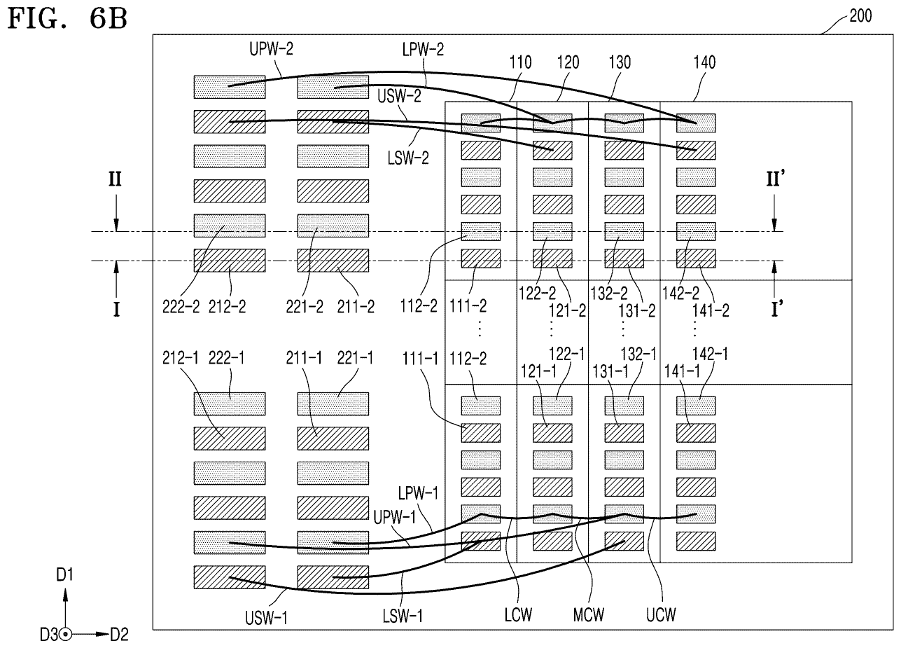

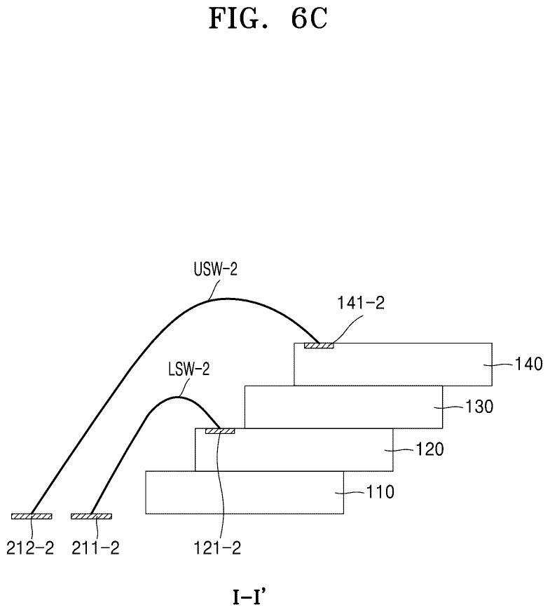

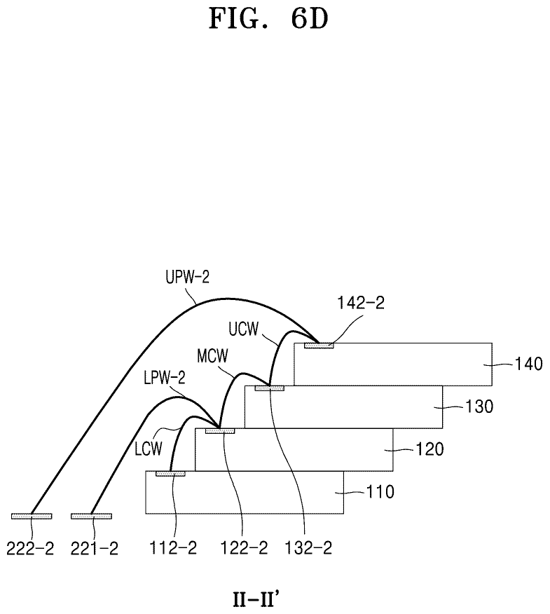

The descriptions that are substantially the same as those with reference to FIGS. 4A to 4E may be omitted. The descriptions with reference to FIGS. 6A to 6D may focus on differences from the descriptions with reference to FIGS. 4A to 4E.

FIG. 6A is a perspective view of a semiconductor package 12 according to an embodiment. FIG. 6B is a plan view of the semiconductor package 12, according to an embodiment, viewed from a position moved in the third direction D3. FIG. 6C is a cross-sectional view of a semiconductor package, taken along line I-I′ in FIG. 6B, according to an embodiment. FIG. 6D is a cross-sectional view of a semiconductor package, taken along line II-II′ in FIG. 6B, according to an embodiment.

According to an embodiment, a package substrate 200 may include first signal P-pads 211-1, second signal P-pads 211-2, first power P-pads 221-1, and second power P-pads 221-2 of a first channel and first signal P-pads 212-1, second signal P-pads 212-2, first power P-pads 222-1, and second power P-pads 222-2 of a second channel.

The first signal P-pads 211-1, the second signal P-pads 211-2, the first power P-pads 221-1, and the second power P-pads 221-2 of the first channel may be spaced apart from the first signal P-pads 212-1, the second signal P-pads 212-2, the first power P-pads 222-1, and the second power P-pads 222-2 of the second channel, respectively. In other words, the P-pads of the first channel may be located closer to the first chip 110 than the P-pads of the second channel.

Referring to FIGS. 6A and 6B, the first power wires PW-1 may include first lower power wires LPW-1 and first upper power wires UPW-1. The first lower power wires LPW-1 may connect the first power pads 112-1 of the first chip 110 to the first power P-pads 221-1 of the first channel. Additionally, the first upper power wires UPW-1 may connect the first power pads 132-1 of the third chip 130 to the first power P-pads 222-1 of the second channel.

The first lower signal wires LSW-1 may include bonding wires connecting the first signal pads 111-1 of the first chip 110 to the first signal P-pads 211-1 of the first channel. The first upper signal wires USW-1 may include bonding wires connecting the first signal pads 131-1 of the third chip 130 to the first signal P-pads 212-1 of the second channel.

The second lower power wires LPW-2 may include bonding wires connecting the second power pads 122-2 of the second chip 120 to the second power P-pads 221-2 of the first channel. The second upper power wires UPW-2 may include bonding wires connecting the second power pads 142-2 of the fourth chip 140 to the second power P-pads 222-2 of the second channel.

The second lower signal wires LSW-2 may include bonding wires connecting the second signal pads 121-2 of the second chip 120 to the second signal P-pads 211-2 of the first channel. The second upper signal wires USW-2 may include bonding wires connecting the second signal pads 141-2 of the fourth chip 140 to the second signal P-pads 212-2 of the second channel.

Referring to FIG. 6D, as described above, the middle chip-to-chip wire MCW, the lower chip-to-chip wire LCW, and the second lower power wires LPW-2 may contact each other on the upper surface of one of the second power pads 122-2 of the second chip 120. As the structure in which the middle chip-to-chip wire MCW, the lower chip-to-chip wire LCW, and the second lower power wire LPW-2 are in contact with each other is the same as the structure shown in FIG. 4E, descriptions that are substantially the same as those given above.

The semiconductor package 12 having the structure shown in FIGS. 6A to 6D may implement a dual channel memory system. Even in the semiconductor package 12, which implements the dual-channel memory system, as described above, the electrical shorts between bonding wires may not occur or may be inhibited.

Although a molding film covering or overlapping multiple chips and multiple bonding wires is not shown or described in the above drawings and descriptions of the drawings, this is only an example for convenience of explanation. That is, multiple chips and multiple bonding wires shown in FIGS. 2A to 6D may be at least partially surrounded by the molding film, wherein the molding film may include an insulating polymer (e.g., epoxy molding compound).

Although structures in which two chips and four chips are stacked are shown and described in the above drawings and descriptions of the drawings, the present disclosure may be applied to structures in which various numbers of chips, such as 6, 8, or 16, are stacked.

Although a structure in which two chips forming a single rank are stacked, a structure in which four chips forming a dual rank are stacked, and a structure in which four chips forming a dual channel are stacked are shown and described in the above drawings and descriptions of the drawings, the present disclosure may be applied to structures in which multiple chips forming various numbers of channels, such as 3, 4, or 5, are stacked.

Although the drawings of the present disclosure show that each of the number of signal pads and the number of power pads included in each chip is 6, this is only an example for convenience of explanation. Each chip included in a semiconductor package may include various numbers of signal pads and power pads (e.g., 16).

In addition, although the drawings of the present disclosure show the package substrate as including 12 pads, this is only an example for convenience of explanation. The package substrate included in the semiconductor package may include various numbers of pads.

Additionally, although signal pads and power pads are shown and described for convenience of explanation in the above drawings and descriptions of the drawings, each chip and the package substrate may include various types of pads, such as RDQS pads, WCK pads, and CA pads.

While the present disclosure has been particularly shown and described with reference to embodiments thereof, it will be understood that various changes in form and details may be made therein without departing from the spirit and scope of the following claims.

What is claimed is:

1. A semiconductor package comprising:
a package substrate comprising first power P-pads and second power P-pads configured to transmit power/ground signals and first signal P-pads and second signal P-pads configured to transmit data signals;
a lower layer chip that is on the package substrate and comprises first power L-pads and second power L-pads configured to transmit the power/ground signals and first signal L-pads and second signal L-pads configured to transmit the data signals; and
an upper layer chip that is on and offset from the lower layer chip in a first direction that is parallel to an upper surface of the package substrate, the upper layer chip comprising first power U-pads and second power U-pads configured to transmit the power/ground signals and first signal U-pads and second signal U-pads configured to transmit the data signals,
wherein, in a first region of the package substrate, the first power P-pads and the first signal P-pads are alternatingly stacked in a second direction that is parallel to the upper surface of the package substrate, the first power L-pads and the first signal L-pads are alternatingly stacked in the second direction, and the first power U-pads and the first signal U-pads are alternatingly stacked in the second direction,
wherein, in a second region of the package substrate that is spaced apart from the first region in the second direction, the second power P-pads and the second signal P-pads are alternatingly stacked in the second direction, the second power L-pads and the second signal L-pads are alternatingly stacked in the second direction, and the second power U-pads and the second signal U-pads are alternatingly stacked in the second direction, and
a plurality of bonding wires that electrically connect the first power U-pads and the second power U-pads and the first power L-pads and the second power L-pads to each other, respectively, the second power U-pads and the second power P-pads to each other, and the second signal U-pads and the second signal P-pads to each other.

2. The semiconductor package of claim 1, wherein:
the plurality of bonding wires comprises power wires and chip-to-chip wires in the second region,
each of the power wires electrically connects each of the second power U-pads to each of the second power P-pads,
each of the chip-to-chip wires electrically connects each of the second power U-pads to each of the second power L-pads, and
the power wires and the chip-to-chip wires are in contact with each other on an upper surface of each of the second power U-pads.

3. The semiconductor package of claim 2, wherein:
each of the power wires and the chip-to-chip wires comprises a bonding ball,
the bonding ball of each of the chip-to-chip wires is on the upper surface of each of the second power U-pads,
the bonding ball of each of the power wires is on the bonding ball of each of the chip-to-chip wires, and
a loop height of the power wires in a third direction that is perpendicular to the upper surface of the package substrate is greater than a loop height of the chip-to-chip wires in the third direction.

4. The semiconductor package of claim 1, wherein:
the first signal U-pads are not electrically connected to the first signal P-pads, the second signal P-pads, the first signal L-pads, and the second signal L-pads, and
the first power L-pads are electrically connected to the first power P-pads, respectively, through ones of the plurality of bonding wires.

5. The semiconductor package of claim 4, wherein:
the plurality of bonding wires comprises power wires and chip-to-chip wires in the first region,
each of the power wires electrically connects each of the first power L-pads to each of the first power P-pads,
each of the chip-to-chip wires electrically connects each of the first power L-pads to each of the first power U-pads, and
the power wires and the chip-to-chip wires are in contact with each other on an upper surface of each of the second power L-pads.

6. The semiconductor package of claim 1, wherein:
the second signal L-pads are not electrically connected to the second signal U-pads and the second signal P-pads, and
the second power L-pads are not electrically connected to the second power P-pads.

7. The semiconductor package of claim 1, wherein:
the upper layer chip and the lower layer chip are included in a first rank, and
a number of the first signal L-pads, a number of the first signal U-pads, a number of the second signal L-pads, and a number of the second signal U-pads each correspond to half of the number of data bits input to or output from the first rank.

8. The semiconductor package of claim 7, wherein the number of the data bits is 16 bits, and the number of the first signal L-pads, the number of the first signal U-pads, the number of the second signal L-pads, and the number of the second signal U-pads are each 8.

9. The semiconductor package of claim 7, wherein the number of the data bits is 24 bits, and the number of the first signal L-pads, the number of the first signal U-pads, the number of the second signal L-pads, and the number of the second signal U-pads are each 12.

10. A semiconductor package comprising:
a package substrate comprising first power P-pads and second power P-pads configured to transmit power/ground signals, and first signal P-pads and second signal P-pads configured to transmit data signals; and
first to fourth chips that are stacked on top of each other, offset from each other in a first direction that is perpendicular to an upper surface of the package substrate, and on the package substrate, wherein each of the first to fourth chips comprises first power pads and second power pads configured to transmit the power/ground signals and first signal pads and second signal pads configured to transmit the data signals,
wherein, in a first region of the package substrate, the first power P-pads and the first signal P-pads are alternatingly stacked in a second direction that is parallel to the upper surface of the package substrate, and the first power pads and the first signal pads of each of the first to fourth chips are alternatingly stacked in the second direction,
wherein, in a second region of the package substrate that is spaced apart from the first region in the second direction, the second power P-pads and the second signal P-pads are alternatingly stacked in the second direction, and the second power pads and the second signal pads of each of the first to fourth chips are alternatingly stacked in the second direction, and
a plurality of bonding wires that electrically connect the first power pads and the second power pads of the second to fourth chips to each other, the first power pads and the second power pads of the first to third chips to each other, the second power pads of the second and fourth chips and the second power P-pads to each other, and the second signal pads of the second and fourth chips and the second signal P-pads to each other.

11. The semiconductor package of claim 10,
wherein the plurality of bonding wires comprises lower power wires, lower chip-to-chip wires and middle chip-to-chip wires in the second region,
the lower power wires, the lower chip-to-chip wires and the middle chip-to-chip wires are in contact with each other on an upper surface of each of the second power pads of the second chip,
each of the lower power wires electrically connects the second power pads of the second chip to the second power P-pads,
each of the lower chip-to-chip wires electrically connects the second power pads of the second chip to the second power pads of the first chip, and
each of the middle chip-to-chip wires electrically connects the second power pads of the second chip to the second power pads of the third chip.

12. The semiconductor package of claim 11, wherein:
a bonding stitch of each of the middle chip-to-chip wires is on the upper surface of each of the second power pads of the second chip,
a bonding ball of each of the lower chip-to-chip wires is on the bonding stitch of each of the middle chip-to-chip wires, and
a bonding ball of each of the lower power wires is on the bonding ball of each of the lower chip-to-chip wires.

13. The semiconductor package of claim 10,
wherein the plurality of the bonding wires comprises upper power wires and upper chip-to-chip wires in the second region,
the upper power wires and the upper chip-to-chip wires are in contact with each other on an upper surface of each of the second power pads of the fourth chip,
each of the upper power wires electrically connects the second power pads of the fourth chip to the second power P-pads, and
each of the upper chip-to-chip wires electrically connects the second power pads of the fourth chip to the second power pads of the third chip.

14. The semiconductor package of claim 13, wherein:
a bonding ball of each of the upper chip-to-chip wires is on the upper surface of each of the second power pads of the fourth chip, and
a bonding ball of each of the upper power wires is on the bonding ball of each of the upper chip-to-chip wires.

15. The semiconductor package of claim 10, wherein:
the first chip and the second chip are included in a first rank,
the third chip and the fourth chip are included in a second rank, and
each of a number of first signal pads and a number of second signal pads of each of the first to fourth chips corresponds to half the number of data bits output from the first rank or the second rank.

16. The semiconductor package of claim 10, wherein the first signal pads of the second and fourth chips are not electrically connected to the first signal pads of the first and third chips and the package substrate, and the first power pads of the first chip are electrically connected to the first power P-pads, respectively, by the plurality of bonding wires.

17. The semiconductor package of claim 10, wherein the second signal pads of the first and third chips are not electrically connected to the second signal pads included of the second and fourth chips and the package substrate, and the second power pads of the first and third chips are not electrically connected to the second power P-pads.

18. A semiconductor package comprising:
a package substrate comprising a first channel and a second channel, the first channel comprising first power P-pads, second power P-pads, first signal P-pads and second signal P-pads, the second channel comprising first power P-pads, second power P-pads, first signal P-pads and second signal P-pads; and
first to fourth chips that are stacked on top of each other, offset from each other in a first direction that is perpendicular to an upper surface of the package substrate, and on the package substrate, wherein each of the first to fourth chips comprises first and second power pads configured to transmit power/ground signals and first and second signal pads configured to transmit data signals,
wherein, in a first region of the package substrate, the first power P-pads and the first signal P-pads of the first channel are alternatingly stacked in a second direction that is parallel to the upper surface of the package substrate, the first power P-pads and the first signal P-pads of the second channel are alternatingly stacked in the second direction, and the first power pads and the first signal pads of each of the first to fourth chips are alternatingly stacked in the second direction,
wherein, in a second region of the package substrate that is spaced apart from the first region in the second direction, the second power P-pads and the second signal P-pads of the first channel are alternatingly stacked in the second direction, the second power P-pads and the second signal P-pads of the second channel are alternatingly stacked in the second direction, and the second power pads and second signal pads of each of the first to fourth chips are alternatingly stacked in the second direction, and
a plurality of bonding wires that electrically connect the first power pads and the second power pads of the second to fourth chips and the first power pads and the second power pads of the first to third chips, respectively, to each other, the second power pads of the second chip and the second power P-pads of the first channel to each other, the second power pads of the fourth chip and the second power P-pads of the second channel to each other, the second signal pads of the second chip and the second signal P-pads of the first channel to each other, and the second signal pads of the fourth chip and the second signal P-pads of the second channel to each other.

19. The semiconductor package of claim 18, wherein the first power P-pads, the first signal P-pads, the second power P-pads and the second signal P-pads of the first channel are spaced apart from first the power P-pads, the first signal P-pads, the second power P-pads and the second signal P-pads of the second channel, respectively, in the first direction.

20. The semiconductor package of claim 19, wherein:
the first signal pads of the second chip and the fourth chip are not electrically connected to the first signal pads of the first chip, the third chip, and the package substrate,
the first power pads of the first chip and the third chip are electrically connected to the first power P-pads of the first channel and the first power P-pads of the second channel, respectively, by the plurality of bonding wires, and
the first signal pads of the first chip the third chip are electrically connected to the first signal P-pads of the first channel and the first signal P-pads of the second channel, respectively, by the plurality of bonding wires.
